(19) United States
(12) Patent Application Publication
(10) Pub. No.: US 2024/0276645 A1
(43) Pub. Date: Aug. 15, 2024

(54) PRINTED WIRING BOARD

(71) Applicant: SUMITOMO ELECTRIC PRINTED CIRCUITS, INC., Shiga (JP)

(72) Inventors: Kou NOGUCHI, Shiga (JP); Seiji MORITA, Shiga (JP); Ryou SHIMAOKA, Shiga (JP)

(73) Assignee: SUMITOMO ELECTRIC PRINTED CIRCUITS, INC., Shiga (JP)

(21) Appl. No.: 18/292,439

(22) PCT Filed: Jul. 28, 2022
(86) PCT No.: PCT/JP2022/029140

§ 371 Date: Jan. 26, 2024

(30) Foreign Application Priority Data
Jul. 30, 2021 (JP) 2021-126236

(51) Int. Cl. H05K 1/16; H01F 5/00

(52) U.S. Cl. CPC H05K 1/165; H01F 5/003

(57) ABSTRACT

A printed wiring board according to one aspect of the present disclosure includes a substrate, and a wiring layer disposed on the substrate and having a spiral wiring line forming a planar coil. When one direction in a winding direction of the entire wiring line in plan view is defined as a positive direction, the wiring layer has a first portion for reducing a density of a current flowing in the positive direction.

### TECHNICAL FIELD

The present disclosure relates to a printed wiring board.

The present application claims priority based on Japanese Patent Application No. 2021-126236 filed on Jul. 30, 2021, and the entire contents of the Japanese patent application are incorporated herein by reference.

### BACKGROUND ART

Printed wiring boards are widely used to constitute circuits of various electronic devices. In recent years, with the size reduction of electronic devices, the size reduction of printed wiring boards and the increase in wiring density of printed wiring boards have been increasingly progressing. As such a printed wiring board, a printed wiring board including a substrate and a wiring layer disposed on the substrate and having a spiral wiring line forming a planar coil is used.

As such a printed wiring board, there has been proposed a printed wiring board used together with a magnet and constituting an actuator together with the magnet (refer to Japanese Unexamined Patent Application Publication No. 2012-89700). According to this printed wiring board, thrust for moving the magnet can be obtained by the magnetic field generated by causing a current to flow through the wiring line.

### CITATION LIST

### Patent Literature

PTL 1: Japanese Unexamined Patent Application Publication No. 2012-89700

### SUMMARY OF INVENTION

A printed wiring board according to one aspect of the present disclosure includes a substrate, and a wiring layer disposed on the substrate and having a spiral wiring line forming a planar coil. When one direction in a winding direction of the entire wiring line in plan view is defined as a positive direction, the wiring layer has a first portion for reducing a density of a current flowing in the positive direction.

### BRIEF DESCRIPTION OF DRAWINGS

FIG. 1 is a schematic plan view illustrating a printed wiring board according to a first embodiment.

FIG. 2 is a schematic sectional view illustrating a cross section taken along line AA of the printed wiring board in FIG. 1.

FIG. 3 is a schematic plan view illustrating a printed wiring board according to a second embodiment.

FIG. 4 is a schematic sectional view illustrating a cross section taken along line BB of the printed wiring board in FIG. 3.

FIG. 5 is a schematic plan view illustrating a printed wiring board according to a third embodiment, the view illustrating directions of a current in a state where the current flowing through a wiring line is increased with time.

FIG. 6 is a schematic sectional view illustrating a cross section taken along line CC of the printed wiring board in FIG. 5.

FIG. 7 is a view of the printed wiring board in FIG. 5, the view illustrating directions of a current in a state where the current flowing through a wiring line is constant with time.

FIG. 8 is a view of the printed wiring board in FIG. 5, the view illustrating directions of a current in a state where the current flowing through a wiring line is decreased with time.

FIG. 9 is a schematic plan view illustrating a printed wiring board according to a fourth embodiment.

FIG. 10 is a schematic sectional view illustrating a cross section taken along line DD of the printed wiring board in FIG. 9.

### DESCRIPTION OF EMBODIMENTS

### Problems to be Solved by Present Disclosure

In the above-described printed wiring board used in an actuator, the thrust generated for the magnet may be excessively large, and in such a case, it may be difficult to finely adjust the position of the magnet.

Meanwhile, in a device including the actuator, there may also be a need to increase the electrical resistance of the printed wiring board in order to secure the amount of current supplied to other components other than the actuator.

In view of the above, an object is to provide a printed wiring board in which the thrust and the electrical resistance can be appropriately adjusted.

### Advantageous Effects of Present Disclosure

According to the printed wiring board of the present disclosure, the thrust of a coil and the electrical resistance can be appropriately adjusted.

### Description of Embodiments of Present Disclosure

First, embodiments of the present disclosure will be enumerated and described.

A printed wiring board according to one aspect of the present disclosure includes a substrate, and a wiring layer disposed on the substrate and having a spiral wiring line forming a planar coil. When one direction in a winding direction of the entire wiring line in plan view is defined as a positive direction, the wiring layer has a first portion for reducing a density of a current flowing in the positive direction.

In the printed wiring board, the wiring layer has the first portion, so that the current density in this first portion is lower than the current density in any other portion in the wiring layer. This enables the thrust exerted on a magnet by the wiring layer to be reduced compared with the case where the wiring layer does not have the first portion, and thus, an excessive increase in the thrust exerted on the magnet by the wiring layer can be suppressed. In addition, such a portion where the thrust is reduced also serves as a portion having a high electrical resistance. Accordingly, since the wiring layer has the first portion, the electrical resistance of the wiring layer can be increased compared with the case where the wiring layer does not have the first portion. Thus, in the printed wiring board, the thrust and the electrical resistance can be appropriately adjusted.

The wiring line may have a first winding portion through which a current flows in the positive direction and a second winding portion which is electrically connected to the first winding portion and through which the current flows in a negative direction opposite to the positive direction in the plan view, the first winding portion and the second winding portion may be formed in a spiral manner as a whole, and the first portion may be constituted by the second winding portion.

In this manner, the wiring line is formed by the first winding portion and the second winding portion in a spiral manner as a whole, and the first portion is constituted by the second winding portion, so that the thrust exerted on the magnet by the wiring layer can be more reliably reduced, and the electrical resistance of the wiring layer can be more reliably increased.

The wiring layer may have a first wiring line through which a current flows in the positive direction in the plan view and a second wiring line which is not electrically connected to the first wiring line and through which no current flows, the first wiring line and the second wiring line may be formed so as to be arranged in a spiral manner as a whole, and the first portion may be constituted by the second wiring line.

In this manner, the wiring layer is formed by the first wiring line and the second wiring line in a spiral manner as a whole, and the first portion is constituted by the second wiring line, so that the thrust exerted on the magnet by the wiring layer can be more reliably reduced, and the electrical resistance of the wiring layer can be more reliably increased.

The wiring line may have a loop circuit portion constituting a loop circuit, and the first portion may be constituted by the loop circuit portion.

In this manner, the wiring line has the loop circuit portion, and the first portion is constituted by the loop circuit portion, so that the thrust exerted on the magnet by the wiring layer can be more reliably reduced, and the electrical resistance of the wiring layer can be more reliably increased.

The wiring line may have a third winding portion having a larger cross-sectional area in a direction perpendicular to an axial direction than any other portion, and the first portion may be constituted by the third winding portion.

In this manner, the wiring line has the third winding portion, and the first portion is constituted by the third winding portion, so that the thrust exerted on the magnet by the wiring layer can be more reliably reduced, and the electrical resistance of the wiring layer can be more reliably increased. Herein, the “axial direction” in the present disclosure means a lengthwise direction of a wiring line.

Herein, “in plan view” means viewing in a direction perpendicular to the substrate. The phrase “a first winding portion and a second winding portion are arranged in a spiral manner as a whole” means that the first winding portion and the second winding portion are arranged along a coiled spiral as a whole. The phrase “a first wiring line and a second wiring line are arranged in a spiral manner as a whole” means that the first wiring line and the second wiring line are arranged along a coiled spiral as a whole. The term “density of a current” means a density of a current flowing through a unit area including at least a wiring line in the same layer (the unit area being a unit area in the plan view), and the unit area includes, in addition to the wiring line, for example, a portion formed of an insulating material, if such a portion is present.

### Details of Embodiments of Present Disclosure

Printed wiring boards according to embodiments of the present disclosure will be described in detail below with reference to the drawings. Note that the term “top surface” in the present embodiments refers to, in the thickness direction of a substrate, a surface on the side on which a wiring line is arranged, and the top and bottom in the embodiments do not define the top and bottom of the printed wiring boards during use.

### First Embodiment

### [Printed Wiring Board]

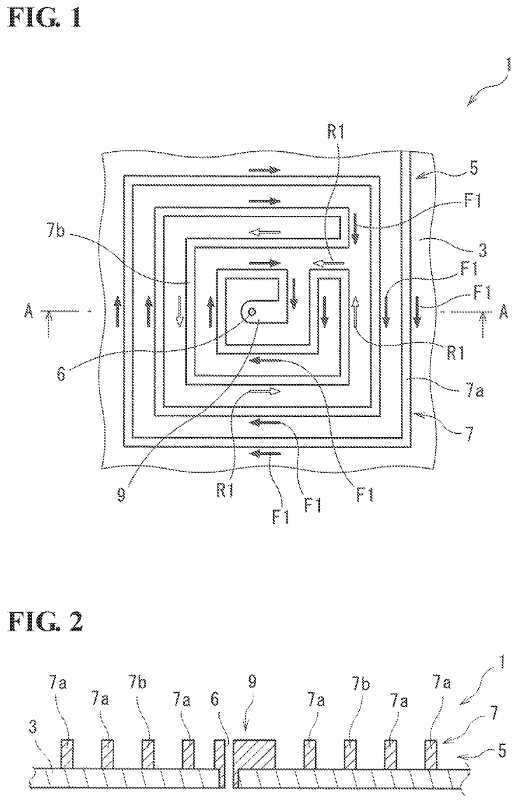

As illustrated in FIGS. 1 and 2, a printed wiring board 1 according to this embodiment includes a substrate 3 and a wiring layer 5 disposed on a top surface (one surface) of the substrate 3 and having a spiral wiring line 7 forming a planar coil. When one direction in a winding direction of the entire wiring line 7 in plan view (viewing the substrate 3 from directly above in the perpendicular direction) is defined as a positive direction (for example, the clockwise direction in FIG. 1, that is, the direction indicated by solid-line arrows F1), the wiring layer 5 has a first portion (a second winding portion 7b in this embodiment) for reducing the density of a current flowing in the positive direction. The first portion is a control portion for reducing the density of the current flowing in the positive direction. The printed wiring board 1 includes a via portion 6 formed so as to extend through the substrate 3 and a land portion 9 of the wiring line 7. Note that the “winding direction of the entire wiring line” means one direction of a winding direction centered on the innermost part of the wiring line. The “one direction in the winding direction of the entire wiring line” can also be referred to as “one direction of a current flowing through a wiring layer in the winding direction of the wiring line”.

In this embodiment, the wiring line 7 has a first winding portion 7a through which a current flows in the positive direction and a second winding portion 7b which is electrically connected to the first winding portion 7a and through which the current flows in a negative direction (the counterclockwise direction in FIG. 1, that is, the direction indicated by open arrows R1) opposite to the positive direction. The first winding portion 7a and the second winding portion 7b are formed in a spiral manner as a whole, and the first portion is constituted by the second winding portion 7b.

### (Substrate)

The substrate 3 is a synthetic resin layer having an insulating property. The substrate 3 is a substrate for forming the wiring layer 5. The substrate 3 is constituted by a plate-shaped member having an insulating property. The plate-shaped member constituting the substrate 3 may be a rigid substrate or a flexible substrate. As the rigid substrate, specifically, a resin plate can be used. A main component of this resin plate is, for example, a glass epoxy material. As the flexible substrate having flexibility, specifically, a resin film can be used. Examples of a main component of this resin film include polyimides, polyethylene terephthalate, liquid crystal polymers, and fluororesins. The “main component” refers to a component that has the highest content and means, for example, a component that accounts for 50% by mass or more in the forming material. The substrate 3 may contain, for example, a resin other than the above resins and additives such as an antistatic agent and a filler.

The lower limit of the average thickness of the substrate 3 is not particularly limited but is preferably 5 μm, more preferably 10 μm. The upper limit of the average thickness of the substrate 3 is not particularly limited but is preferably 200 μm, more preferably 150 μm, still more preferably 100 μm, particularly preferably 50 μm. If the average thickness of the substrate 3 is less than the lower limit, the dielectric strength and mechanical strength of the substrate 3 may become insufficient. On the other hand, if the average thickness of the substrate 3 exceeds the upper limit, the thickness of the printed wiring board 1 may increase unnecessarily. Herein, the term “average thickness” of the substrate 3 means the average of thicknesses measured at any 10 points.

### (Wiring Layer)

The wiring layer 5 is disposed on the top surface of the substrate 3 and has a spiral wiring line 7 forming a planar coil. Specifically, the wiring line 7 has a first winding portion 7a through which a current I-lows in the positive direction (the direction indicated by solid-line arrows F1 in FIG. 1) and a second winding portion 7b which is electrically connected to the first winding portion 7a and through which a current flows in the negative direction (the direction indicated by open arrows R1 in FIG. 1) opposite to the positive direction in the plan view, and the first winding portion 7a and the second winding portion 7b are formed in a spiral manner as a whole. The first portion is constituted by the second winding portion 7b. The wiring line 7 has a land portion 9 at an end on the inner circumferential side thereof.

The second winding portion 7b of the wiring line 7 is turned around such that the direction of the current becomes the negative direction in a part of a winding portion of the wiring line 7 in the winding direction. The second winding portion 7b is further turned around such that the direction of the current becomes the positive direction again and connected to the first winding portion 7a. In the wiring line 7 having such a second winding portion 7b, for example, as illustrated in FIG. 1, a part of the first winding portion 7a is first arranged in a spiral manner in the positive direction from an end on the outer circumferential side of the wiring line 7 toward an end on the inner circumferential side, the second winding portion 7b is subsequently arranged in a spiral manner such that the direction of the current is turned around to the negative direction with respect to the part of the first winding portion 7a, and the remainder of the first winding portion 7a is subsequently arranged in a spiral manner in a state of being turned around such that the direction of the current becomes the positive direction with respect to the second winding portion 7b.

The arrangement is performed such that, when a current is caused to flow from the end on the outer circumferential side of the wiring line 7 toward the end on the inner circumferential side, apparently in the plan view, the direction of the current is the positive direction in the first winding portion 7a, whereas the direction of the current is the negative direction in the second winding portion 7b. As a result, in the second winding portion 7b, the thrust exerted on a magnet is small, and the electrical resistance is high, compared with the first winding portion 7a.

While the present embodiment has described the clockwise direction in FIG. 1 as the positive direction, conversely, the counterclockwise direction in FIG. 1 may be defined as the positive direction. In this case, when a current is caused to flow from the end on the inner circumferential side of the wiring line 7 toward the end on the outer circumferential side, in plan view, the direction of the current becomes the positive direction (corresponding to the counterclockwise direction in FIG. 1) in the first winding portion 7a, whereas the direction of the current becomes the negative direction (corresponding to the clockwise direction in FIG. 1) in the second winding portion 7b.

As described above, the second winding portion 7b is formed together with the first winding portion 7a in a spiral manner as a whole.

The second winding portion 7b can be arranged at any position in the winding direction of the wiring line 7, but is preferably arranged at a position other than both ends of the wiring line 7, that is, at a central portion. The arrangement of the second winding portion 7b at such a position enables the thrust exerted on the magnet by the wiring layer 5 to be more reliably reduced and enables the electrical resistance of the wiring layer 5 to be more reliably increased.

The thrust induced in a magnet by a coil usually increases as the position is closer to a portion facing the center (the position of the center of gravity) of the magnet in the coil and decreases as the position is away from the center. Accordingly, when the second winding portion 7b is arranged in a central portion of the wiring line 7, the generation of a peak in the thrust can be suppressed to smoothen the thrust so as to be close to a similar value as a whole.

The total length of the second winding portion 7b in the winding direction can be represented as the number of turns of the second winding portion 7b constituting a part of the spiral. The number of turns of the second winding portion 7b is not particularly limited and can be appropriately set in accordance with the degree of magnitude of the magnetic field generated by energization, that is, for example, the degree of reduction in the thrust exerted on the magnet and the degree of increase in the electrical resistance, as described above. For example, the lower limit of the number of turns of the second winding portion 7b is preferably 0.5, more preferably 0.8, still more preferably 0.9. If the number of turns is less than the lower limit, it may be difficult to sufficiently reduce the thrust exerted on the magnetic force by the wiring layer 5, and it may be difficult to sufficiently increase the electrical resistance of the wiring layer 5. On the other hand, for example, the upper limit of the number of turns of the second winding portion 7b is preferably 2, more preferably 1.5, still more preferably 1.2, even still more preferably 1.1. If the number of turns exceeds the upper limit, the shape of the spiral is distorted, and consequently, the thrust exerted on the magnet by the wiring layer 5 may be excessively small, and the electrical resistance of the wiring layer 5 may be excessively high.

The average line width of the second winding portion 7b is preferably set as in the average line width of the first winding portion 7a from the viewpoint of easily manufacturing the wiring line 7.

The lower limit of the average line width of the wiring line 7 (that includes the first winding portion 7a and the second winding portion 7b but that does not include the land portion 9) is preferably 10 μm, more preferably 15 μm, still more preferably 20 μm, even still more preferably 25 μm. If the average line width of the wiring line 7 is less than the lower limit, it may be difficult to form the wiring line 7. In addition, adhesion strength between the substrate 3 and the wiring line 7 decreases, and consequently, the wiring line 7 may be peeled off from the substrate 3. On the other hand, the upper limit of the average line width of the wiring line 7 is preferably 300 μm, more preferably 200 μm, still more preferably 100 μm, even still more preferably 50 μm. If the average line width of the wiring line 7 exceeds the upper limit, the wiring density may not satisfy the requirement. Herein, the term “average line width” of the wiring line 7 refers to a value obtained by averaging, in the winding direction, the maximum widths in a cross section perpendicular to the axial direction of the wiring line 7. This “average line width” is synonymous with an “average line width” used below.

The lower limit of the average distance between adjacent winding portions (that includes the first winding portion 7a and the second winding portion 7b but that does not include the land portion 9) in the wiring line 7 is preferably 10 μm, more preferably 15 μm, still more preferably 20 μm, even still more preferably 25 μm. If the average distance between winding portions of the wiring line 7 is less than the lower limit, a short circuit may occur between the winding portions. On the other hand, the upper limit of the average distance between winding portions of the wiring line 7 is preferably 300 μm, more preferably 200 μm, still more preferably 100 μm, even still more preferably 50 μm. If the average distance between winding portions of the wiring line 7 exceeds the upper limit, the wiring density may not satisfy the requirement, and the average line width of the wiring line 7 may vary when the wiring line 7 is formed by the semi-additive method. Herein, the term “average distance” between winding portions of the wiring line 7 refers to a value obtained by averaging, in the winding direction, the minimum distances between facing side edges of adjacent winding portions in a cross section perpendicular to the axial direction of the wiring line 7. Note that the average distance between winding portions of the wiring line 7 includes an average distance between adjacent first winding portions 7a, an average distance between adjacent second winding portions 7b when the second winding portion 7b has more than one turn, and an average distance between a first winding portion 7a and a second winding portion 7b adjacent to each other. This “average distance” is synonymous with an “average distance” used below.

The lower limit of the average thickness of the wiring line 7 (that includes the first winding portion 7a and the second winding portion 7b but that does not include the land portion 9) is preferably 10 μm, more preferably 15 μm, still more preferably 25 μm, particularly preferably 30 μm. If the average thickness of the wiring line 7 is less than the lower limit, the current density in the wiring line 7 may be excessively high, and the electrical resistance of the wiring line 7 may be excessively high. On the other hand, the tipper limit of the average thickness of the wiring line 7 is preferably 95 μm, more preferably 85 μm, still more preferably 75 μm, particularly preferably 70 μm. If the average thickness of the wiring line 7 exceeds the upper limit, the thickness of the printed wiring board 1 may increase unnecessarily. The term “average thickness” of the wiring line 7 refers to a value obtained by averaging, in the winding direction, the maximum heights of the wiring line 7 in a cross section perpendicular to the axial direction of the wiring line 7. This “average thickness” is synonymous with an “average thickness” used below.

The printed wiring board 1 according to this embodiment can be manufactured by a publicly known method and can be manufactured using, for example, the subtractive method, the semi-additive method, or the like.

When the subtractive method is used, the printed wiring board 1 can be manufactured by, for example, forming, by electrolytic plating, a plating layer over the entire surface of a conductive underlayer of the substrate 3 having the conductive underlayer on a surface thereof, forming a resist pattern on the plating layer, etching the conductive underlayer and the plating layer using the resist pattern as a mask, and, after the etching, removing the resist pattern to form the wiring line 7.

When the semi-additive method is used, the printed wiring board 1 can be formed by, for example, forming a resist pattern on a conductive underlayer of the substrate 3 having the conductive underlayer on a surface thereof, performing electrolytic plating in a region of the conductive underlayer, the region not having the resist pattern thereon, to form the wiring line 7, and subsequently removing the resist pattern and the conductive underlayer located in a region not having the wiring line 7 thereon. Note that, after the resist pattern and the conductive underlayer are removed, electrolytic plating can be further performed to form the wiring line 7.

### Advantages

In the printed wiring board 1 according to this embodiment, the wiring layer 5 has the first portion (the second winding portion 7b in this embodiment), so that the current density in this first portion is lower than the current density in any other portion in the wiring layer 5. This enables the thrust exerted on a magnet by the wiring layer 5 to be reduced compared with the case where the wiring layer 5 does not have the first portion, and thus, an excessive increase in the thrust exerted on the magnet by the wiring layer 5 can be suppressed. In addition, such a portion where the thrust is reduced also serves as a portion having a high electrical resistance. Accordingly, since the wiring layer 5 has the first portion, the electrical resistance of the wiring layer 5 can be increased compared with the case where the wiring layer 5 does not have the first portion. Thus, in the printed wiring board 1, the thrust and the electrical resistance can be appropriately adjusted.

In this embodiment, the wiring line 7 is formed by the first winding portion 7a and the second winding portion 7b in a spiral manner as a whole, and the first portion is constituted by the second winding portion 7b, so that the thrust exerted on the magnet by the wiring layer 5 can be more reliably reduced, and the electrical resistance of the wiring layer 5 can be more reliably increased.

### Second Embodiment

### [Printed Wiring Board]

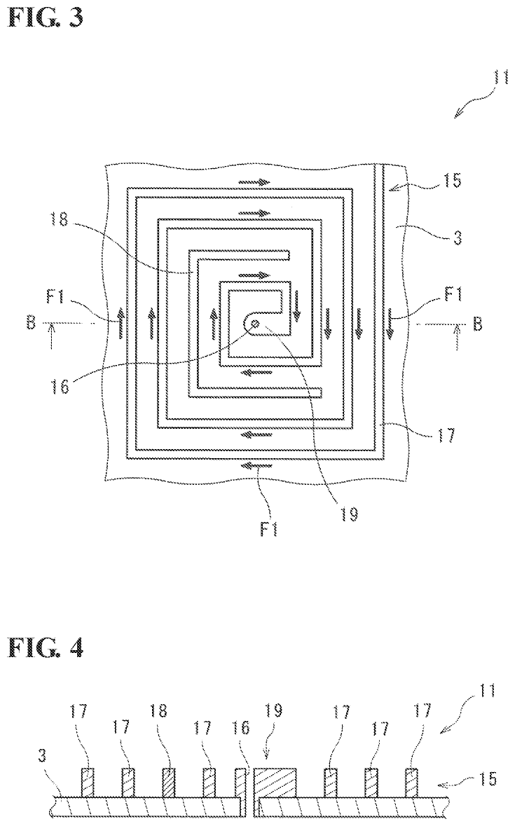

As illustrated in FIGS. 3 and 4, a printed wiring board 11 according to this embodiment includes a substrate 3 and a wiring layer 15 disposed on a top surface (one surface) of the substrate 3 and having a spiral first wiring line 17 forming a planar coil. When one direction in a winding direction of the entire first wiring line 17 in plan view (viewing the substrate 3 from directly above in the perpendicular direction) is defined as a positive direction (for example, the clockwise direction in FIG. 3, that is, the direction indicated by solid-line arrows F1), the wiring layer 5 has a first portion (a second wiring line 18 in this embodiment) for reducing the density of a current flowing in the positive direction. The printed wiring board 1 includes a via portion 16 formed so as to extend through the substrate 3 and a land portion 19 of the first wiring line 17.

In this embodiment, the wiring layer 15 has a first wiring line 17 through which a current flows in the positive direction in the plan view and a second wiring line 18 which is not electrically connected to the first wiring line 17 and through which no current flows, the first wiring line 17 and the second wiring line 18 are formed so as to be arranged in a spiral manner as a whole, and the first portion is constituted by the second wiring line 18. The second wiring line 18 corresponds to a dummy wiring line.

### (Substrate)

A substrate similar to that of the first embodiment can be used as the substrate 3.

### (Wiring Layer)

The wiring layer 15 is disposed on the top surface of the substrate 3 and has a spiral first wiring line 17 forming a planar coil. The wiring layer 15 has the first wiring line 17 through which a current flows in the positive direction in the plan view and a second wiring line 18 which is not electrically connected to the first wiring line 17 and through which no current flows, the first wiring line 17 and the second wiring line 18 are formed so as to be arranged in a spiral manner as a whole, and the first portion is constituted by the second wiring line 18. The first wiring line 17 has a land portion 19 at an end on the inner circumferential side thereof.

The first wiring line 17 is formed in a spiral manner in the positive direction (the direction indicated by solid-line arrows F1 in FIG. 3) while a part thereof bypasses the second wiring line 18. In the wiring layer 15 having such a first wiring line 17 and a second wiring line 18, for example, as illustrated in FIG. 3, a part of the winding portion of the first wiring line 17 is first arranged in a spiral manner in the positive direction from an end on the outer circumferential side of the first wiring line 17 toward an end on the inner circumferential side, the subsequent part of the winding portion of the first wiring line 17 is subsequently arranged in a spiral manner in the positive direction while bypassing the second wiring line 18 in plan view (while being spaced apart from the second wiring line 18 so as not to be in contact with the second wiring line 18), and the remainder of the winding portion of the first wiring line 17 is subsequently arranged in a spiral manner.

When a current is caused to flow from the end on the outer circumferential side of the first wiring line 17 toward the end on the inner circumferential side, the current flows through the first wiring line 17 in the positive direction, whereas no current flows through the second wiring line 18. As a result, in the region where the second wiring line 18 is present, the thrust exerted on a magnet by the wiring layer 15 is small, and the electrical resistance of the wiring layer 15 is high, compared with the regions of the wiring layer 15 on the inner circumferential side and the outer circumferential side with respect to the second wiring line 18. Consequently, in the region of the wiring layer 15 where the second wiring line 18 is present, the thrust exerted on the magnet is small, and the electrical resistance is high, compared with the other regions.

While the present embodiment has described the clockwise direction in FIG. 3 as the positive direction, conversely, the counterclockwise direction in FIG. 3 may be defined as the positive direction. Also in this case, when a current is caused to flow from the end on the inner circumferential side of the first wiring line 17 toward the end on the outer circumferential side (in the counterclockwise direction in FIG. 3), in the region of the wiring layer 15 where the second wiring line 18 is present, the thrust exerted on the magnet is small, and the electrical resistance is high, compared with the other regions.

As described above, the second wiring line 18 is arranged, at a position that is vacant due to the bypass of the first wiring line 17, together with the first wiring line 17 in a spiral manner as a whole.

FIG. 3 illustrates an embodiment in which a single second wiring line 18 is formed; however, the number of second wiring lines 18 may be appropriately set in accordance with, for example, the degree of reduction in the thrust excited on the magnet by the wiring layer 15 and the degree of increase in the electrical resistance of the wiring layer 15. The distance between winding portions of the first wiring line 17 can also be appropriately set in accordance with the number of second wiring lines 18 so as to bypass the second wiring lines 18.

The average line width of the first wiring line 17 (that does not include the land portion 9) can be set as in the average line width of the wiring line 7 of the first embodiment described above.

The average distance between adjacent winding portions of the first wiring line 17 (that does not include the land portion 9) can be set as in the average distance of the wiring line 7 of the first embodiment described above.

The average thickness of the first wiring line 17 (that does not include the land portion 9) can be set as in the average thickness of the wiring line 7 of the first embodiment described above.

The second wiring line 18 is arranged in the winding direction described above. The second wiring line 18 can be arranged at any position between winding portions of the first wiring line 17. The arrangement of this second wiring line 18 can be appropriately set, for example, so as to reduce the thrust exerted on the magnet as described above in accordance with the use or the like. In consideration of this point, for example, the second wiring line 18 can be arranged as the outermost circumference outside the first wiring line 17. Alternatively, for example, the second wiring line 18 can be arranged as the innermost circumference inside the first wiring line 17. Alternatively, for example, the second wiring line 18 can be arranged between winding portions of the first wiring line 17 on the inner circumferential side with respect to the first turn on the outer circumferential side of the first wiring line 17 and on the outer circumferential side with respect to the first turn on the inner circumferential side. Of these, the second wiring line 18 is preferably arranged as the outermost circumference outside the first wiring line 17, arranged as the innermost circumference inside the first wiring line 17, or arranged between winding portions of the first wiring line 17 in a part between the outermost circumference and the innermost circumference. When the second wiring line 18 is arranged at such a position, the thrust exerted on the magnet by the wiring layer 5 can be more reliably reduced, and the electrical resistance of the wiring layer 5 can be more reliably increased.

As in the first embodiment described above, when the second wiring line 18 is arranged at a position other than both ends of the first wiring line 17, more specifically, a part between the outermost circumference and the innermost circumference as described above, the generation of a peak in the thrust can be suppressed to smoothen the thrust so as to be close to a similar value as a whole.

The total length of the second wiring line 18 in the winding direction can be represented as the number of turns of the second wiring line 18 constituting a part of the spiral. The number of turns of the second wiring line 18 is not particularly limited and can be appropriately set in accordance with the degree of magnitude of the magnetic field generated by energization, that is, for example, the degree of reduction in the thrust exerted on the magnet and the degree of increase in the electrical resistance, as described above. For example, the lower limit of the number of turns of the second wiring line 18 is preferably 0.5, more preferably 0.8, still more preferably 0.9. If the number of turns is less than the lower limit, it may be difficult to sufficiently reduce the thrust exerted on the magnet by the wiring layer 15, and it may be difficult to sufficiently increase the electrical resistance of the wiring layer 15. On the other hand, the upper limit of the number of turns of the second wiring line 18 is preferably 2, more preferably 1.5, still more preferably 1.2, even still more preferably 1.1. If the number of turns exceeds the upper limit, the shape of the spiral is distorted, and consequently, the thrust exerted on the magnet by the wiring layer 15 may be excessively small, and the electrical resistance of the wiring layer 15 may be excessively high.

The average line width of the second wiring line 18 is preferably set as in the average line width of the first wiring line 17 from the viewpoint of easily manufacturing the wiring layer 15.

The average distance between the second wiring line 18 and a winding portion of the first wiring line 17 adjacent to the second wiring line 18 is preferably set as in the average distance between winding portions of the first wiring line 17 from the viewpoint of easily manufacturing the wiring layer 15. For the same reason, the average distance between a leading end of the second wiring line 18 and a winding portion of the first wiring line 17 adjacent to the leading end is also preferably set to as in the average distance between winding portions of the first wiring line 17. For the same reason, when the second wiring line 18 has a winding portion having more than one turn, the average distance between winding portions of the second wiring line 18 adjacent to each other is preferably the same as the average distance between winding portions of the first wiring line 17. As described above, when the average distance between winding portions of the first wiring line 17, the average distance between a winding portion of the first wiring line 17 and a winding portion of the second wiring line 18, and the average distance between winding portions of the second wiring line 18 are within the above ranges, in the formation of a first wiring line 17 and a second wiring line 18 on the substrate 3 by the semi-additive method, in addition to the above, variations in the average line widths of the first wiring line 17 and the second wiring line 18 can be reduced.

The average thickness of the second wiring line 18 is preferably set as in the average thickness of the first wiring line 17 from the viewpoint of easily manufacturing the wiring layer 15.

The printed wiring board 11 according to this embodiment can be manufactured as in the above-described first embodiment by a publicly known subtractive method, semi-additive method, or the like using a resist pattern capable of forming the first wiring line 17 and the second wiring line 18.

### Advantages

In the printed wiring board 11 according to this embodiment, the wiring layer 15 has the first portion (the second wiring line 18 in this embodiment), so that the current density in the first portion in the wiring layer 15 is lower than the current density in any other portion. This enables the thrust exerted on a magnet by the wiring layer 15 to be reduced compared with the case where the wiring layer 15 does not have the first portion, and thus, an excessive increase in the thrust exerted on the magnet by the wiring layer 15 can be suppressed. In addition, such a portion where the thrust is reduced also serves as a portion having a high electrical resistance. Accordingly, since the wiring layer 15 has the first portion, the electrical resistance of the wiring layer 15 can be increased compared with the case where the wiring layer 15 does not have the first portion. Thus, in the printed wiring board 11, the thrust and the electrical resistance can be appropriately adjusted.

In this embodiment, the wiring layer 15 is formed by the first wiring line 17 and the second wiring line 18 in a spiral manner as a whole, and the first portion is constituted by the second wiring line 18, so that the thrust exerted on the magnet by the wiring layer 15 can be more reliably reduced, and the electrical resistance of the wiring layer 15 can be more reliably increased.

### Third Embodiment

### [Printed Wiring Board]

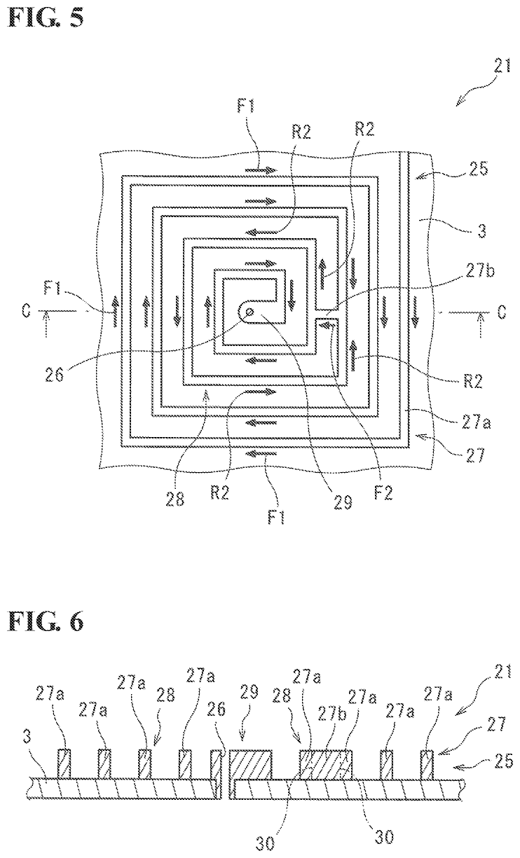

As illustrated in FIGS. 5, 6, and 7, a printed wiring board 21 according to this embodiment includes a substrate 3 and a wiring layer 25 disposed on a top surface (one surface) of the substrate 3 and having a spiral wiring line 27 forming a planar coil. When one direction in a winding direction of the entire wiring line 27 in plan view (viewing the substrate 3 from directly above in the perpendicular direction) is defined as a positive direction (for example, the clockwise direction indicated by solid-line arrows F1 in FIG. 5), the wiring layer 25 has a first portion (a loop circuit portion 28 in this embodiment) for reducing the density of a current flowing in the positive direction. The printed wiring board 21 includes a via portion 26 formed so as to extend through the substrate 3 and a land portion 29 of the wiring line 27.

In this embodiment, the wiring line 27 has a loop circuit portion 28 constituting a loop circuit, and the first portion is constituted by the loop circuit portion 28.

### (Substrate)

A substrate similar to that of the first embodiment can be used as the substrate 3.

### (Wiring Layer)

The wiring layer 25 is disposed on the top surface of the substrate 3 and has a spiral wiring line 27 forming a planar coil. The wiring line 27 has, as a part thereof, a loop circuit portion 28 constituting a loop circuit, and the first portion is constituted by the loop circuit portion 28. The wiring line 27 has a land portion 29 at an end on the inner circumferential side thereof.

The loop circuit portion 28 of the wiring line 27 is formed by electrically connecting, by a connecting portion 27b, adjacent parts of a winding portion (fifth winding portion 27a) of the wiring line 27 formed in a spiral manner in the positive direction indicated by solid-line arrows F1 in FIG. 5 to each other. In the wiring line 27 having such a fifth winding portion 27a and a connecting portion 27b, for example, as illustrated in FIG. 5, the fifth winding portion 27a is first arranged in a spiral manner in the positive direction indicated by solid-line arrows F1 in FIG. 5 from an end on the outer circumferential side of the wiring line 27 toward an end on the inner circumferential side, and, at any position of the fifth winding portion 27a in the winding direction, the connecting portion 27b is arranged so as to electrically connect parts of the fifth winding portion 27a to each other, the parts being adjacent to each other in a direction perpendicular to the winding direction. The connecting portion 27b constitutes an introduction path for introducing a current flowing through the fifth winding portion 27a into the loop circuit portion 28, as indicated by solid-line arrow F2 in FIG. 5.

When a current is caused to flow from the end on the outer circumferential side of the wiring line 27 toward the end on the inner circumferential side, depending on the state of the flowing current with time as described later, the density of the current flowing in the positive direction through the loop circuit portion 28 constituted by parts of the fifth winding portion 27a and the connecting portion 27b is lower than the density of the current flowing in the positive direction through a part arranged on the outer circumferential side (the upstream side in the positive direction) with respect to the connecting portion 27b in the fifth winding portion 27a. As a result, in the loop circuit portion 28, the thrust exerted on a magnet is small, and the electrical resistance is high, compared with the fifth winding portion 27a that does not constitute a loop circuit. In FIG. 6, for ease of understanding, boundaries 30 between the connecting portion 27b and the fifth winding portion 27a are indicated by chain double-dashed lines.

While the present embodiment has described the clockwise direction in FIG. 5 as the positive direction, conversely, the counterclockwise direction in FIG. 5 may be defined as the positive direction. Also in this case, when a current is caused to flow from the end on the inner circumferential side of the wiring line 27 toward the end on the outer circumferential side in the counterclockwise direction in FIG. 5, in the loop circuit portion 28, the thrust exerted on the magnet is small, and the electrical resistance is high, compared with the fifth winding portion 27a that does not constitute a loop circuit.

The flow of the current through the loop circuit portion 28 in this embodiment will now be described in detail.

Usually, when a current flows through the wiring line 27 serving as a coil, induced electromotive force due to the magnetic field generated from the wiring line 27 is generated in the loop circuit portion 28 depending on the state of the flowing current, and a current corresponding to the induced electromotive force flows through the loop circuit portion 28.

In the case where a current flows through the wiring line 27 in this manner, in a state where the current flowing through the wiring line 27 is increased with time, the current flows through the loop circuit portion 28 in a direction (negative direction indicated by solid-line arrows R2 in FIG. 5) opposite to the current flowing through the fifth winding portion 27a, as illustrated in FIG. 5. As a result, in the loop circuit portion 28, the density of the current flowing in the positive direction is reduced.

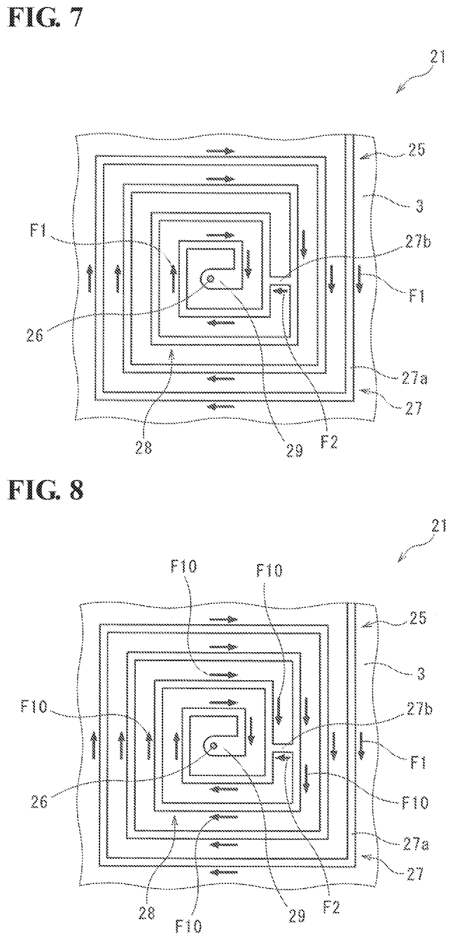

On the other hand, in the case where a current flows through the wiring line 27, in a state where the current flowing through the wiring line 27 is constant with time, no current flows through the loop circuit portion 28, as illustrated in FIG. 7. As a result, in the loop circuit portion 28, the density of the current flowing in the positive direction is reduced.

In contrast to these, in the case where a current flows through the wiring line 27, in a state where the current flowing through the wiring line 27 is decreased with time, the current flows through the loop circuit portion 28 in the same direction (the positive direction in this case) as the current flowing through the fifth winding portion 27a, as illustrated in FIG. 8. As a result, in the loop circuit portion 28, the density of the current flowing in the positive direction indicated by solid-line arrows F10 in FIG. 8 is increased.

Accordingly, when the wiring line 27 has the loop circuit portion 28, it is necessary to cause the current to flow through the wiring line 27 such that the current flowing through the wiring line 27 is increased with time or the current flowing through the wiring line 27 is constant with time.

The average line width of the fifth winding portion 27a (that does not include the land portion 29) of the wiring line 27 can be set as in the average line width of the wiring line 7 of the first embodiment described above.

The average distance between adjacent parts of the fifth winding portion 27a (that does not include the land portion 29) can be set as in the average distance between adjacent winding portions of the wiring line 7 of the first embodiment described above.

Furthermore, by setting the average distance of the fifth winding portion 27a in this manner, a variation in the average line width of the wiring line 27 can be reduced, in particular, when the wiring line 27 is formed on the substrate 3 by the semi-additive method described later.

The average thickness of the fifth winding portion 27a (that does not include the land portion 29) can be set as in the average thickness of the wiring line 7 of the first embodiment described above.

FIG. 5 illustrates an embodiment in which a single connecting portion 27b is formed between parts of the fifth winding portion 27a of the wiring line 27; however, the number of connecting portions 27b, that is, the number of loop circuit portions 28 may be appropriately set in accordance with, for example, the degree of reduction in the thrust exerted on the magnet by the wiring layer 25 and the degree of increase in the electrical resistance of the wiring layer 25. In addition, for example, the arrangement of the connecting portion 27b between parts of the fifth winding portion 27a can also be appropriately set in accordance with the degree of reduction in the thrust, the degree of increase in the electrical resistance, and the like.

The connecting portion 27b in the wiring line 27 is preferably arranged at a position other than both ends of the fifth winding portion 27a, that is, at a central portion. The arrangement of the connecting portion 27b at such a position enables the thrust exerted on the magnet by the wiring layer 25 to be more reliably reduced and enables the electrical resistance of the wiring layer 25 to be more reliably increased.

As in the first embodiment described above, when the connecting portion 27b is arranged at a central portion of the fifth winding portion 27a as described above, the generation of a peak in the thrust can be suppressed to smoothen the thrust so as to be close to a similar value as a whole.

The average line width and the average thickness of the connecting portion 27b are preferably set as in the average line width and the average thickness of the fifth winding portion 27a from the viewpoint of easily manufacturing the wiring layer 25. Note that the average length of the connecting portion 27b in the direction (the direction in which the current flows) perpendicular to the winding direction is set depending on the average distance between parts of the fifth winding portion 27a.

The printed wiring board 21 according to this embodiment can be manufactured as in the above-described first embodiment by a publicly known subtractive method, semi-additive method, or the like using a resist pattern capable of forming the fifth winding portion 27a and the connecting portion 27b of the wiring line 27.

### Advantages

In the printed wiring board 21 according to this embodiment, the wiring layer 25 has the first portion, so that the current density in the first portion is lower than the current density in any other portion in the wiring layer 25. This enables the thrust exerted on a magnet by the wiring layer 25 to be reduced compared with the case where the wiring layer 25 does not have the first portion, and thus, an excessive increase in the thrust exerted on the magnet by the wiring layer 25 can be suppressed. In addition, such a portion where the thrust is reduced also serves as a portion having a high electrical resistance.

Accordingly, since the wiring layer 25 has the first portion, the electrical resistance of the wiring layer 25 can be increased compared with the case where the wiring layer 25 does not have the first portion. Thus, in the printed wiring board 21, the thrust and the electrical resistance can be appropriately adjusted.

In this embodiment, the wiring line 27 has the loop circuit portion 28, and the first portion is constituted by the loop circuit portion 28, so that the thrust exerted on the magnet by the wiring layer 25 can be more reliably reduced, and the electrical resistance of the wiring layer 25 can be more reliably increased.

### Fourth Embodiment

### [Printed Wiring Board]

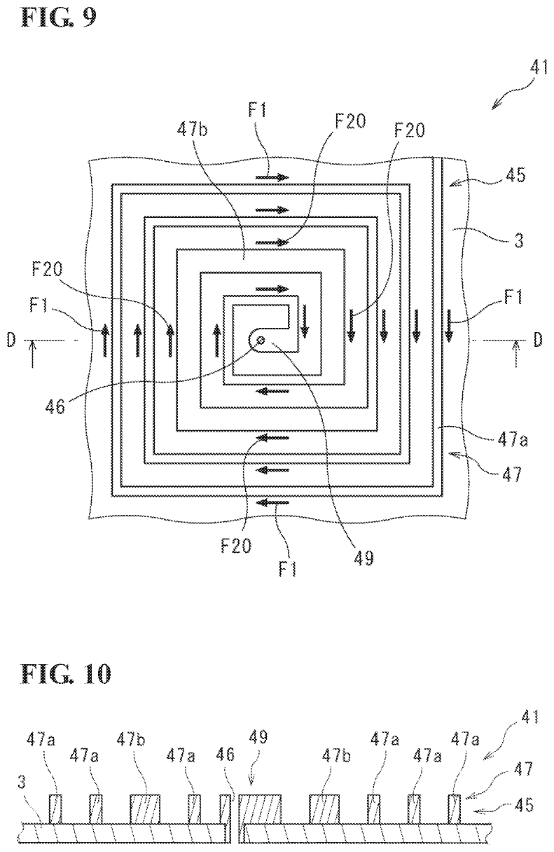

As illustrated in FIGS. 9 and 10, a printed wiring board 41 according to this embodiment includes a substrate 3 and a wiring layer 45 disposed on a top surface (one surface) of the substrate 3 and having a spiral wiring line 47 forming a planar coil. When one direction in a winding direction of the entire wiring line 47 in plan view (viewing the substrate 3 from directly above in the perpendicular direction) is defined as a positive direction (for example, the clockwise direction in FIG. 9, that is, the direction indicated by solid-line arrows F1), the wiring layer 45 has a first portion (a third winding portion 47b in this embodiment) for reducing the density of a current flowing in the positive direction. The printed wiring board 41 includes a via portion 46 formed so as to extend through the substrate 3 and a land portion 49 of the wiring line 47.

In this embodiment, the wiring line 47 has a third winding portion 47b having a larger cross-sectional area in a direction perpendicular to the axial direction (hereinafter, also simply referred to as a “cross-sectional area”) than any other portion (a fourth winding portion 47a), and the first portion is constituted by the third winding portion 47b.

### (Substrate)

A substrate similar to that of the first embodiment can be used as the substrate 3.

### (Wiring Layer)

The wiring layer 45 is disposed on the top surface of the substrate 3 and has a spiral wiring line 47 forming a planar coil. The wiring line 47 has a third winding portion 47b having a larger cross-sectional area than a fourth winding portion 47a, and the first portion is constituted by the third winding portion 47b. The wiring line 47 has a land portion 49 at an end on the inner circumferential side thereof.

The wiring line 47 is formed in a spiral manner in the positive direction (the direction indicated by solid-line arrows F1 in FIG. 9) and formed so as to have the fourth winding portion 47a and the third winding portion 47b. The cross-sectional area of the third winding portion 47b is larger than the cross-sectional area of the fourth winding portion 47a. The phrase “the cross-sectional area of the third winding portion 47b is larger than the cross-sectional area of the fourth winding portion 47a” means that a cross-sectional area at any position of the third winding portion 47b is larger than an average cross-sectional area of the fourth winding portion 47a determined as the average of cross-sectional areas at any ten points in the winding direction. In the wiring line 47 having such a fourth winding portion 47a and a third winding portion 47b, for example, as illustrated in FIG. 9, a part of the fourth winding portion 47a is first arranged in a spiral manner in the positive direction from an end on the outer circumferential side of the wiring line 47 toward an end on the inner circumferential side, the third winding portion 47b having a larger cross-sectional area than the fourth winding portion 47a is subsequently arranged in a spiral manner in the positive direction, and the remainder of the fourth winding portion 47a is subsequently arranged in a spiral manner.

When a current is caused to flow from the end on the outer circumferential side of the wiring line 47 toward the end on the inner circumferential side, the current flows through the fourth winding portion 47a and the third winding portion 47b in the positive direction (the direction indicated by solid-line arrows F1 in FIG. 9), and the current density of a current F20 flowing through the third winding portion 47b is lower than the current density of a current F1 flowing through the fourth winding portion 47a. As a result, in the region of the third winding portion 47h, the thrust exerted on a magnet is small, and the electrical resistance in the region of the third winding portion 47b is high, compared with the region of the fourth winding portion 47a in the wiring layer 45. Consequently, in the region in the wiring layer 45 where the third winding portion 47b is present, the thrust exerted on the magnet is small, and the electrical resistance is high, compared with the region of the fourth winding portion 47a, which is any other region.

While the present embodiment has described the clockwise direction in FIG. 9 as the positive direction, conversely, the counterclockwise direction in FIG. 9 may be defined as the positive direction. Also in this case, when a current is caused to flow from the end on the inner circumferential side of the wiring line 47 toward the end on the outer circumferential side (in the counterclockwise direction in FIG. 9), in the region of the wiring layer 45 where the third winding portion 47b is present, the thrust exerted on the magnet is small, and the electrical resistance is high, compared with any other region (the region of the fourth winding portion 47a).

The average line width of the fourth winding portion 47a (that does not include the land portion 49) of the wiring line 47 can be set as in the average line width of the wiring line 7 of the first embodiment described above.

The average distance between adjacent parts of the fourth winding portion 47a (that does not include the land portion 49) can be set as in the average line width between adjacent winding portions of the wiring line 7 of the first embodiment described above.

The average thickness of the fourth winding portion 47a (that does not include the land portion 49) can be set as in the average thickness of the wiring line 7 of the first embodiment described above.

The third winding portion 47b of the wiring line 47 is preferably arranged at a position other than both ends of the wiring line 47, that is, at a central portion. The arrangement of the third winding portion 47b at such a position enables the thrust exerted on the magnet by the wiring layer 45 to be more reliably reduced and enables the electrical resistance of the wiring layer 45 to be more reliably increased.

As in the first embodiment described above, when the third winding portion 47b is arranged on the central side in the winding direction as described above, the generation of a peak in the thrust can be suppressed to smoothen the thrust so as to be close to a similar value as a whole.

The number of third winding portions 47b included in the wiring line 47 is not particularly limited and may be one or two or more. When the wiring line 47 has a plurality of third winding portions, the number of third winding portions 47b and the average distances may be appropriately set in accordance with, for example, the degree of reduction in the thrust exerted on the magnet by the wiring layer 45 and the degree of increase in the electrical resistance of the wiring layer 45.

The average line width of the third winding portion 47b can be appropriately set so as to be larger than the average line width of the fourth winding portion 47a. The average line width of the third winding portion 47b may be larger than the average distance between adjacent parts of the fourth winding portion 47a. In addition, the average line width of the third winding portion 47b can be appropriately set in accordance with the degree of reduction in the thrust exerted on the magnet by the wiring layer 45 and the degree of increase in the electrical resistance of the wiring layer 45.

For example, the lower limit of the average line width of the third winding portion 47b is preferably 30 μm, more preferably 45 μm, still more preferably 60 μm, even still more preferably 75 μm. If the average line width of the third winding portion 47b is less than the lower limit, the degree of reduction in the thrust by the wiring layer 45 and the degree of increase in the electrical resistance of the wiring layer 45 may be excessively small. On the other hand, the upper limit of the average line width of the third winding portion 47b is preferably 900 μm, more preferably 600 μm, still more preferably 300 μm, even still more preferably 150 μm. If the average line width of the third winding portion 47b exceeds the upper limit, the degree of reduction in the thrust by the wiring layer 45 and the degree of increase in the electrical resistance of the wiring layer 45 may be excessively large. In addition, a short circuit may occur between the third winding portion 47b and the fourth winding portion 47a.

The average distance between the third winding portion 47b and the fourth winding portion 47a adjacent to this third winding portion 47b can be set as in the fourth winding portion 47a, that is, as in the average distance of the wiring line 7 of the first embodiment described above.

When the third winding portion 47b is wound to have more than one turn, the average distance between adjacent parts of the third winding portion 47b can also be set as in the fourth winding portion 47a, that is, as in the average distance of the wiring line 7 of the first embodiment described above.

The total length of the third winding portion 47b in the winding direction can be represented as the number of turns of the third winding portion 47b constituting a part of the spiral. The number of turns of the third winding portion 47b is not particularly limited and can be appropriately set in accordance with the degree of magnitude of the magnetic field generated by energization, that is, for example, the degree of reduction in the thrust exerted on the magnet and the degree of increase in the electrical resistance, as described above. For example, the lower limit of the number of turns of the third winding portion 47b is preferably 0.5, more preferably 0.8, still more preferably 0.9. If the number of turns is less than the lower limit, it may be difficult to sufficiently reduce the thrust exerted on the magnetic force by the wiring layer 45, and it may be difficult to sufficiently increase the electrical resistance of the wiring layer 45. On the other hand, for example, the upper limit of the number of turns of the third winding portion 47b is preferably 2, more preferably 1.5, still more preferably 1.2, even still more preferably 1.1. If the number of turns exceeds the upper limit, the shape of the spiral is distorted, and consequently, the thrust exerted on the magnet by the wiring layer 45 may be excessively small, and the electrical resistance of the wiring layer 45 may be excessively high.

The average thickness of the third winding portion 47b can be set as in the average thickness of the fourth winding portion 47a.

The printed wiring board 41 according to this embodiment can be manufactured as in the above-described first embodiment by a publicly known subtractive method, semi-additive method, or the like using a resist pattern capable of forming the fourth winding portion 47a and the third winding portion 47b of the wiring line 47.

### Advantages

In the printed wiring board 41 according to this embodiment, the wiring layer 45 has the first portion, so that the current density in the first portion becomes lower than the current density in any other portion in the wiring layer 45. This enables the thrust exerted on a magnet by the wiring layer 45 to be reduced compared with the case where the wiring layer 45 does not have the first portion, and thus, an excessive increase in the thrust exerted on the magnet by the wiring layer 45 can be suppressed. In addition, such a portion where the thrust is reduced also serves as a portion having a high electrical resistance. Accordingly, since the wiring layer 45 has the first portion, the electrical resistance of the wiring layer 45 can be increased compared with the case where the wiring layer 45 does not have the first portion. Thus, in the printed wiring board 41, the thrust and the electrical resistance can be appropriately adjusted.

In this embodiment, the wiring line 47 has the third winding portion 47b, and the first portion is constituted by the third winding portion 47b, so that the thrust exerted on the magnet by the wiring layer 45 can be more reliably reduced, and the electrical resistance of the wiring layer 45 can be more reliably increased.

### Other Embodiments

It is to be understood that the embodiments disclosed herein are only illustrative and non-restrictive in all respects. The scope of the present invention is not limited to the configurations of the embodiments but is defined by the claims, and is intended to cover meanings equivalent to the scope of the claims and all modifications within the scope.

In the above embodiments, embodiments in which a wiring layer is disposed on a top surface (one surface) of a substrate have been described. Alternatively, an embodiment in which a wiring layer is also disposed on a bottom surface (the other surface) of a substrate may be employed.

In the above embodiments, embodiments in which a planar coil formed by a wiring line is wound in a rectangular shape, but the shape of the coil is not particularly limited. Alternatively, an embodiment in which the coil is wound in a circular shape, an elliptical shape, or the like may be employed. The number of turns of the coil is also not particularly limited and may be appropriately set in relation to a magnet used, etc.

### REFERENCE SIGNS LIST

1, 11, 21, 41 printed wiring board
3 substrate
5, 15, 25, 45 wiring layer
7, 27, 47 wiring line
7a first winding portion
7b second winding portion
9, 19, 29, 49 land portion
6, 16, 26, 46 via portion
17 first wiring line
18 second wiring line
27a fifth winding portion
27b connecting portion
28 loop circuit portion
boundary between connecting portion and fifth winding portion
47a fourth winding portion
47b third winding portion
F1 positive direction
F2 direction of current flowing into connecting portion
F10 direction of current flowing through loop circuit portion
F20 direction of current flowing through third winding portion
R1 negative direction
R2 direction opposite to current flowing through fifth winding portion

1. A printed wiring board comprising:
a substrate; and
a wiring layer disposed on the substrate and having a spiral wiring line forming a planar coil,
wherein when one direction in a winding direction of the entire wiring line in plan view is defined as a positive direction,
the wiring layer has a first portion for reducing a density of a current flowing in the positive direction.

2. The printed wiring board according to claim 1,
wherein the wiring line has
a first winding portion through which a current flows in the positive direction, and
a second winding portion which is electrically connected to the first winding portion and through which the current flows in a negative direction opposite to the positive direction in the plan view,
the first winding portion and the second winding portion are formed in a spiral manner as a whole, and
the first portion is constituted by the second winding portion.

3. The printed wiring board according to claim 1,
wherein the wiring layer has
a first wiring line through which a current flows in the positive direction in the plan view, and
a second wiring line which is not electrically connected to the first wiring line and through which no current flows,
the first wiring line and the second wiring line are formed so as to be arranged in a spiral manner as a whole, and
the first portion is constituted by the second wiring line.

4. The printed wiring board according to claim 1,
wherein the wiring line has a loop circuit portion constituting a loop circuit, and
the first portion is constituted by the loop circuit portion.

5. The printed wiring board according to claim 1,
wherein the wiring line has a third winding portion having a larger cross-sectional area in a direction perpendicular to an axial direction than any other portion, and
the first portion is constituted by the third winding portion.
